(19) United States
(12) Patent Application Publication
(10) Pub. No.: US 2025/0013720 A1
(43) Pub. Date: Jan. 9, 2025

(54) METHOD AND DEVICE FOR SIGNAL PATTERN RECOGNITION

(71) Applicant: H-NEXT GMBH, Erlangen (DE)

(72) Inventor: Oliver HEID, Erlangen (DE)

(73) Assignee: H-NEXT GMBH, Erlangen (DE)

(21) Appl. No.: 18/712,744

(22) PCT Filed: Nov. 22, 2022
(86) PCT No.: PCT/EP2022/082732

§ 371 Date: May 23, 2024

(30) Foreign Application Priority Data
Nov. 24, 2021 (DE) 10 2021 130 772.4

(51) Int. Cl. G06F 18/243

(52) U.S. Cl. CPC G06F 18/24323

(57) ABSTRACT

A method is for triggering, for signal pattern recognition on the basis of the maintenance or violation of signal amplitude corridors, proceeding from a continuous data stream which is sampled in a time-discrete manner and is divided into blocks which are each formed from a number of sampling values given as a power of two (2n). On each of these blocks, a tree structure of minimum and maximum pairs is built. Each of these pairs is a node of the tree and includes the minimum value and the maximum value of the two directly assigned pairs or values in the next level down. Corridors of a mask which is used for signal pattern recognition are shifted from sampling value to sampling value via the data blocks. The trees are built up, like the depth-first searches, by parallel data processing.

### CROSS-REFERENCE TO RELATED APPLICATIONS

This application is a National Stage Application of PCT/EP2022/082732, filed Nov. 22, 2022, which claims benefit of priority to German Patent Application No. 102021130772.4, filed Nov. 24, 2021, and which applications are incorporated herein by reference. To the extent appropriate, a claim of priority is made to each of the above disclosed applications.

### FIELD OF THE INVENTION

The invention relates to a method for signal pattern recognition, in particular for triggering. Furthermore, the invention relates to a device suitable for carrying out such a method.

### PRIOR ART

US 2007/0217694 A1 discloses a digital acquisition system that compresses sampled data before storage. The acquisition system includes a device for digitizing an electrical signal, thereby generating a sampled data stream. In addition, the digital acquisition system includes means for parallel compression of the sampled data stream. Various compression schemes are used, including a low-pass filter scheme. At the same time, the digital acquisition system should be particularly suitable for detecting peaks. For this purpose, for example, a data block containing 128 values is first divided into 64 pairs of values. Each pair of values is to be understood as a combination of a minimum value and a maximum value. In the next step of the data acquisition and processing system according to US 2007/0217694 A1, the maximum value of two neighboring min-max pairs is determined. The same procedure is followed for the minimum values. In this way, a next layer of data is created that only contains 32 max values and 32 min values. This scheme is continued until the two extreme values of all original 128 values have been extracted.

From US 2009/0153559 A1 a method for automatically generating a frequency domain mask for a selected input signal is known. In the known method, frequency domain data representing the selected input signal is reduced to produce a reduced waveform. The reduced waveform can be plotted using a user-selected frequency offset.

US 2008/0054967 A1 describes a method for correcting errors in a sequential sampling time base, wherein a sampling time for the sequential sampling time base is defined by a time duration of a combination of a fine analog delay and a coarse delay. The method according to US 2008/0054967 A1 comprises measuring a time difference between a trigger at which the fine analog delay starts the measurement time and the occurrence of a digital pulse of a stable clock.

A digital oscilloscope with glitch detection described in US 2010/0052653 A1 comprises, among other things, a synchronous random access memory, a digital signal processing unit, an analog-to-digital converter and a digital signal processor. The latter processor includes a plurality of processing blocks designed to process the digitized analog signal data and detect glitches in this data.

From WO 2014/072271 A1 a device for determining a trigger condition for a rare signal event is known. With the help of the known device, level- or time-based statistical parameters are detected and frequency distributions are continuously updated. The trigger condition can be a level-based and/or time-based threshold value that is exceeded or undershot by the detected signal. Frequency distributions can be determined for different level-based thresholds.

U.S. Pat. No. 4,585,975 A discloses a multi-channel oscilloscope with digital trigger signal channels. The oscilloscope includes a trigger threshold generator and works with Boolean functions, among others.

U.S. Pat. No. 4,843,309 A describes a method for timing a waveform for digital oscilloscopes. This method involves making first and second data recordings from a periodic signal, which relate to a first and a second waveform, respectively. For the first waveform, an autocorrelation value is generated from the first data recording. Furthermore, a cross-correlation value is generated between the first and second waveforms. Misalignment between waveforms should be detectable by comparing the autocorrelation value with the cross-correlation value.

A digital oscilloscope with parallel acquisition and signal post-processing is known from DE 10 2014 208 464 A1. Here, sampling values of a signal are acquired in individual time ranges, each of which is defined in relation to a trigger time of a trigger event. Subsequently, post-processing of the sampling values acquired in individual time ranges is provided.

Another device for digital triggering is described in DE 10 2006 021 075 A1. In this case, a measurement signal is assumed to be superimposed with a noise signal.

In principle, a trigger can be initiated by an analog or a digital signal. In the simplest case, triggering means that a trigger signal is activated when a threshold value is exceeded or undershot. If more complicated trigger patterns are present, which is particularly relevant in digital signal processing, the generation of a trigger signal requires more computational effort. More complicated trigger conditions, especially in the form of temporally extended signal amplitude corridors, require such a large amount of computational effort that time gaps arise in which the signal cannot be analyzed. In order to avoid such dead times, redundant means for signal acquisition and processing can be provided, which inevitably increases the equipment effort.

### SUMMARY OF THE INVENTION

The object of the invention is to expand the possibilities of signal pattern recognition, in particular in connection with triggering, compared to the cited prior art, wherein the signal analysis effort is essentially independent of the complexity of the trigger condition and can be parallelized across a large number of computing units, so that even with a high data rate and complex trigger conditions, seamless signal evaluation should be possible whole aiming at a particularly favorable ratio between the complexity of a signal pattern to be recognized and the effort in terms of equipment required for recognition.

This object is achieved according to the invention by a method for signal pattern recognition according to claim 1. The object is also achieved by a device according to claim 15. The embodiments and advantages of the invention explained below in connection with the signal pattern recognition device also apply correspondingly to the pattern recognition method and vice versa.

The signal pattern recognition method comprises the following steps:
Discrete-time sampling of a continuous data stream, i.e. acquisition of sampling values that form a signal curve,
dividing the data stream into blocks, wherein the number of sampling values per block corresponds to a power of two,
building at least one min-max tree on each block, in that the sampling values are defined as the first layer of the tree and further layers of the tree are built on this layer, which, in contrast to the first layer, are formed from min-max pairs, wherein each min-max pair is formed from the minimum and the maximum of the two pairs or sampling values lying in the last layer built or already existing, and wherein the tree building takes place at least in a part of the layers which includes the first layer by parallel data processing,
carrying out tree runs which partially cross block limits, i.e. which extend beyond a tree into at least one neighboring tree, for each sampling time, in each case starting in the first layer, for at least one corridor length predetermined by a signal mask, wherein each individual sampling value within the entire corridor length is initially defined as a min-max candidate and two successive min-max candidates are replaced by the min-max pair lying, as the associated node point, in the next layer, provided that all sampling values assigned to this min-max pair also lie within the corridor, and identification of the minimum value and maximum value assigned to the respective sampling time and to the corridor length on the basis of the min-max candidates found by the tree run, wherein one and the same min-max tree is used for a plurality of tree runs to be carried out in parallel,
generating an envelope curve belonging to the signal curve from the minimum and maximum values specific to the corridor length and assigned to a respective sampling time,
testing a trigger condition given by the signal mask for each sampling time by comparison with the envelope curve instead of the original signal, wherein at least part of the testing method is carried out by parallel data processing and wherein Boolean trigger value signals are generated from sampling value to sampling value.

Thus, parallel data processing takes place in several phases of the method. This first involves the build up of the min-max trees on the individual blocks into which the data stream is divided. Only one min-max tree needs to be created per block. The min-max trees represent a multi-use basis for the further method.

The invention is based on the consideration that two fundamentally different approaches can be used to check whether a portion of a signal sequence satisfies a condition given by a mask, in particular a trigger condition:

According to a first conceivable approach, a mask with which a data stream is to be examined is shifted in the smallest possible steps, i.e. from sampling value to sampling value. For example, if a signal sequence has a clock rate of 1 ns, a mask used to examine this signal sequence could, in extreme cases, also only extend over a duration of 1 ns. Masks with significantly longer corridors are also conceivable. For example, a corridor could extend over a duration of 1 ms, that is, 1 million sampling values. Accordingly, in this case, 10⁶ possible mask positions exist within the corridor length. If all comparisons between sampling values falling within the mask are to be carried out for each possible mask position, the limits of conventional data processing systems are quickly reached. Conversely, this means that in this way only a few, not too long masks can be used.

Another possible approach is to evaluate the data stream using an incremental search algorithm. This approach assumes that the time required to execute the search algorithm for each new sampling value is shorter than the time interval between two sampling values. Otherwise, the difference between the time required by the search algorithm and the timing of the data stream from sampling value to sampling value would add up, so that real-time examination of the data stream cannot be maintained over a longer period of time. This shortcoming could be addressed, for example, by not including each of the consecutive sampling values in the analysis or by preprocessing several consecutive sampling values. However, such measures could be at the expense of information originally contained in the data stream, which are present, for example, in the form of very short signal changes.

The invention deviates from the approaches described in that a block-by-block processing, in which adjacent blocks of the data stream are processed separately, is only carried out in an initial method step, wherein a very high processing speed can already be achieved in this method step due to the parallelism of the data processing. This parallelism can in principle enable higher sampling value evaluation rates than the clock frequency of a single arithmetic unit. Starting from 2ⁿ sampling values per data block, the first level of the min-max tree can be built in up to ½×2ⁿ simultaneous calculation steps. At higher levels, the degree of possible parallelism is reduced. The second level can be built in up to ¼×2ⁿ simultaneous calculation steps; in the third level there are a maximum of ⅛×2ⁿ processes that can be carried out in parallel, and so on. The top of the tree is finally formed by a single pair of a minimum value and a maximum value. On a sufficiently large number of parallel arithmetic units, only n serial calculation steps are required to generate a tree over 2ⁿ sampling values. In order to achieve the highest possible degree of parallelism, it is assumed that the number of arithmetic units is at least half the number of sampling values per data block.

Each tree contains the min-max pairs of sampling value intervals starting at index positions that are integer multiples of powers of two. The interval lengths are also powers of two. More precisely, at level k={1 . . . n} the min-max values

(min,max){j*2^{k}−2^{k}+1 . . . j*2^{k}−1}

are stored for j={0 . . . 2^{n-k}−1}.

In a second, parallelizable step of data processing within the framework of the method according to the application, the desired min-max pairs with any given corridor length are obtained at each sampling value position in the form of tree runs.

For corridors with temporally increasing or decreasing upper and lower limits of the slopes A and B per sampling value, the recursive min-max union of two adjacent min-max pairs (min,max){i+1 . . . j}, (min,max){j+1 . . . k} is carried out during tree generation and tree runs according to

$$min \{ i + 1 … k \} = min ( min \{ i + 1 , j \} + B ( k - j ) , min \{ j + 1 .. k \} )$$

$$max \{ i + 1 … k \} = max ( max \{ i + 1 , j \} + A ( k - j ) , max \{ j + 1 .. k \} ) .$$

Each corridor gradient A or B requires its own tree and its own tree runs to generate its own envelope signal. In contrast to the structure of the min-max trees, these tree runs are not bound to the block limits, but can extend into one or more adjacent neighboring trees, so that the resulting envelope can be generated without gaps.

The computational effort to find the desired min-max pairs for each corridor position and length by tree generation and subsequent tree runs is far less than the computational effort to sequentially acquire the number of sampling values in the corresponding corridor length for each corridor position. Thus, at this point in the signal pattern recognition process, there is already a significant saving in data processing steps compared to conventional data processing methods, in which for each interval to be examined all values of this interval must be explicitly included in the analysis. In addition, it is possible to parallelize each of the two calculation steps on a large number of arithmetic units, so that the absolute time required to analyze a block of sampling values is reduced proportionally and a correspondingly larger number of sampling values can be analyzed per unit of time.

Separate tree runs must be carried out for each corridor length and for each corridor gradient. If different corridors of the signal mask have the same length, tree runs are carried out for the corresponding plurality of corridors. Regardless of the extent to which corridor lengths occur multiple times, each corridor length is preferably less than the block length into which the data stream is divided.

From the individual Boolean test results of the signal against the individual corridors, i.e. the min-max pairs against the corridor lower and upper limits, a common Boolean trigger function is generated for each possible mask position along the data stream, which represents whether the signal satisfies the entire signal mask or not.

In any case, the method for signal pattern recognition that can be used for triggering based on compliance with or violation of signal amplitude corridors is based on a time-discretely sampled continuous data stream, which is divided into blocks, each of which is formed from a number of sampling values given as a power of two (2ⁿ). On each of these blocks, a tree structure of minimum-maximum pairs is built, with each of these pairs representing a node of the tree and containing the minimum and maximum values of the two directly associated pairs or values (except for the zeroth level, i.e. the level of the sampling values) in the next lower level of the tree. Corridors of a mask used for signal pattern recognition are shifted from sampling value to sampling value across the data blocks, regardless of their limits, whereby for each position of the corridor, depth-first searches are performed through at least one of the already created trees. The build up of the trees as well as the depth-first searches are performed using parallel data processing. In comparison to a block-wise data evaluation of all sampling values falling within a corridor for each possible mask position, the evaluation based on the already existing tree structures only requires a much less extensive comparison between the minimum and maximum values already found. The method is thus able to evaluate the data stream without interruption even at a high clock frequency of sampling values of, for example, more than 100 MHz.

The signal pattern recognition method is suitable, for example, for signal masks with a single corridor or a plurality of corridors, where each corridor has a constant upper and lower limit. There may also be an overlap between different corridors in terms of time and/or the upper and lower limits of the corridors. Likewise, limits of corridors may not be defined absolutely, but in relation to limits of other corridors.

In contrast to known methods, as described, inter alia, in US 2007/0217694 A1, the method according to the application does not work by decimating data. Rather, minimum and maximum values, which lie within a time interval specified by a signal mask, i.e., corresponding to a corridor length, are determined for each individual sampling value, i.e., digitized value of the input signal. The original sampling rate with which the continuous data stream is sampled is retained.

In further developed embodiments, the signal pattern recognition method is designed for use with signal masks which have at least one corridor with a lower and/or upper limit that varies over its length. In such a case, the envelopes are generated with a distortion that reflects the deviations of the corridor limits from constant limits. In this way, as with corridors with constant limits, compliance with a trigger condition that refers to an extended period of time, namely a period that extends over the length of the corridor, can be checked for each sampling point in time by comparing the corresponding sampling value with a single min-max pair given by the envelope curve. The sampling time thus represents a test point.

If a corridor is not defined by corridor limits that are constant over the entire length of the corridor, for example, lower and upper limits of the corridor with a constant gradient can be given in some portions. In particular, the corridor may only comprise portions in which the gradients of the upper limit of the portion concerned, on the one hand, and the lower limit of the same portion, on the other hand, have different signs. If there are two adjacent portions of this kind, the corridor as a whole can, for example, have the shape of a diamond or a dovetail shape. If a signal is required to be above a lower limit and below an upper limit of a corridor, this corridor represents a so-called positive window. Conversely, if there is a requirement that a signal either falls below a lower limit of a corridor or exceeds an upper limit of the same corridor, a negative window is defined.

There are a wide range of design options when it comes to the size of the blocks into which the continuous data stream is divided. For example, the block on which the min-max tree is to be built contains at least 2¹⁰ and at most 2³⁰ sampling values.

Likewise, a wide variety of design variants are possible with regard to the parallelism of data processing. For example, the min-max tree, which is generated based on the sampling values, can be built up to at least half of the layers, i.e. levels of the tree, through parallel data processing. In particular, the number of tree runs performed in parallel corresponds to at least the square root of the number of sampling values per block.

The signal pattern recognition method is particularly suitable for use with signal sequences with short clock cycles, for example acquisition of sampling values at time intervals of not more than 10 ns, in particular not more than 2 ns or 1 ns. A particular advantage achieved by the parallelism of data processing in several processing phases is that the building up of the min-max trees as well as the tree runs can be carried out in calculation steps that are longer than the time interval between two consecutive sampling values, wherein the parallelism of data processing means that the total number of serial calculation steps per position of the signal mask is less than one.

For example, regardless of the complexity of the signal mask, a trigger time is set when the Boolean trigger value signal changes from “true” to “false”. In this case, the trigger time found is entered into a list. Entries in the list can be made without any other conditions or, for example, taking into account a trigger hold-off period. It is also possible, for example, to make entries in the list only after release by a trigger counter, for example only every second or third event that is considered a trigger event.

The device for signal pattern recognition generally comprises a data acquisition device provided for receiving a clocked signal and a trigger device coupled to this device and designed to carry out the method according to the application. The trigger device can have 128 or more, in particular 1,000 or more, arithmetic units designed for parallel data processing during the build up of the min-max trees and the tree runs. Optionally, the arithmetic units can also be used for the graphical display of sampling values.

According to various possible embodiments, the trigger device comprises a ring memory which is provided for storing at least three blocks of the data stream, whereby the trigger device is designed for the uninterrupted processing of unfiltered sampling values.

The advantage of the invention lies in particular in the fact that even in a fast-clocked, time-discretely sampled continuous data stream, the temporal positions of a predetermined signal pattern can be recognized without dead times. This applies, among other things, to the detection of data frames, eye diagrams and their errors, which occur particularly in the form of so-called glitches and can be of extremely short duration.

### BRIEF DESCRIPTION OF THE DRAWINGS

Multiple exemplary embodiments of the invention are explained in more detail below with reference to a drawing. In the Figs.:

FIG. 1 shows a schematic representation of a method suitable as a digital trigger method for signal pattern recognition, starting from a sequence of sampling values,

FIG. 2 shows a signal mask usable in the trigger method,

FIG. 3 shows the structure of a min-max tree, which is based on the sequence of sampling values and is used several times in the trigger method,

FIG. 4 shows a diagram of a possible sequence of sampling values and an envelope curve formed using a corridor of the signal mask,

FIG. 5 shows a signal mask designed as a negative mask,

FIGS. 6 and 7 each show in a respective diagram a sequence of sampling values and an envelope curve formed using the mask according to FIG. 5,

FIG. 8 shows a block diagram of a device for carrying out the signal pattern recognition method.

### DETAILED DESCRIPTION OF THE INVENTION

Unless otherwise stated, the following explanations refer to all exemplary embodiments.

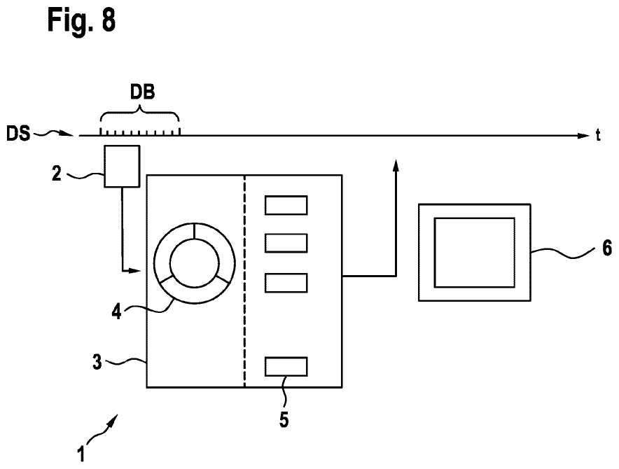

A trigger method generally referred to as a method for signal pattern recognition can be carried out by means of a signal processing device 1 symbolically shown in FIG. 8. Components of the signal processing device 1 are a data acquisition device 2, which is designed to acquire a data stream DS, and a trigger device 3 connected downstream of the data acquisition device 2. The trigger device 3 comprises a ring memory 4 and a plurality of arithmetic units 5, in the present case more than a thousand. Embodiments with a smaller number of arithmetic units 5, for example one hundred and twenty-eight, are also possible. A display device 6 can be used in particular as a display of an oscilloscope, in particular for displaying data frames or eye diagrams which are detected by means of the trigger device 3.

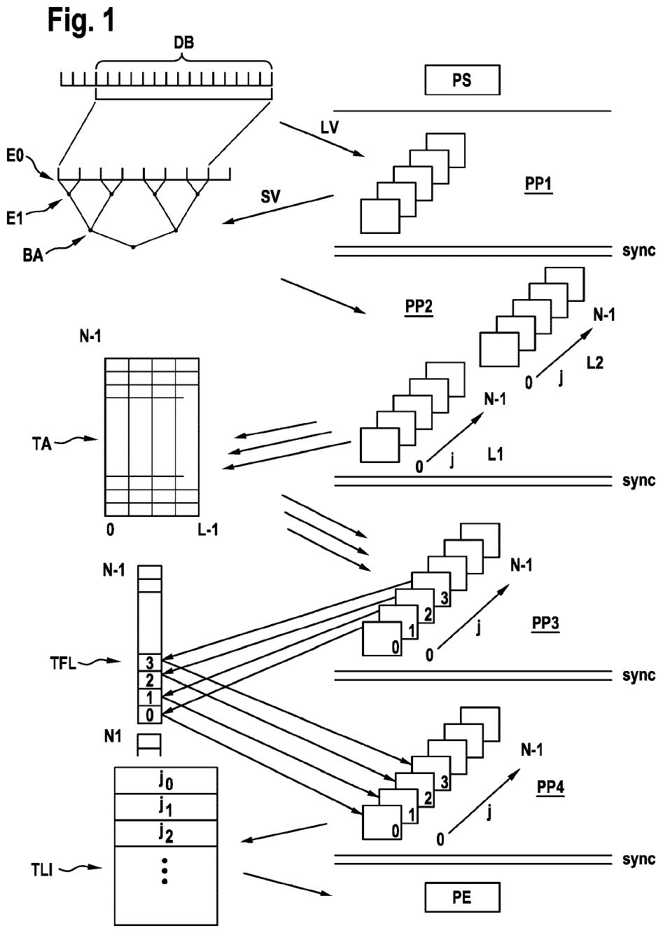

The data stream DS is sampled in a time-discrete manner and divided into data blocks DB, which are also referred to as blocks for short. Regarding the processing of the data blocks DB by means of the signal processing device 1, reference is made below to FIG. 1. In FIG. 1, the left half of the representation illustrates available data and the right half of the representation illustrates the processing of the data. The start of the data processing procedure is marked with PS. The term LV is used for read operations and the term SV is used for write operations. Data blocks DB are read into ring memory 4. As soon as a complete data block DB is available, the building up of a min-max tree BA can begin in a first parallel process PP1.

The digitized sampling values of the data stream DS, from which the data block DB is formed, represent the zeroth level E0 of the min-max tree BA. The width of the min-max tree BA corresponds to a power of two of sampling values. In the case outlined in FIG. 3, the min-max tree BA extends over 64=2⁶ sampling values, for which the notation s is generally used. The sampling values s detected at equal time intervals result in a signal curve generally referred to as SK. The data blocks DB into which the signal curve SK is divided can actually extend over far more than sixty-four sampling values s each. For example, on the order of a million or more sampling values s can fall into a data block DB.

The structure of the min-max tree BA is independent of the later application of a mask MA. In level E0, pairs of sampling values s are formed, that is, in the case of FIG. 3, a total of thirty-two pairs. One of the two values of each pair represents a minimum value, the other value a maximum value, although both values may also overlap. In each case, the corresponding min-max pair is written into level E1. This is done, as indicated in FIG. 1 in step PP1, on the basis of a plurality of parallel data processing processes which are carried out by means of the arithmetic units 5.

From level E1 onwards, individual values are no longer compared, but pairs of values. For each comparison, there are a total of four values from which the minimum and maximum are selected. The next min-max pair selected in this way is written to the next higher level E2. This process is also carried out through parallel data processing. If necessary, synchronization takes place, referred to as sync in FIG. 1. The building of the min-max tree BA is completed when the min-max pair of the entire tree BA, located in the sixth level in FIG. 3, is found. The min-max trees BA, which are each built on a data block DB, represent static structures for the further method, that can be used multiple times, in particular for different masks MA.

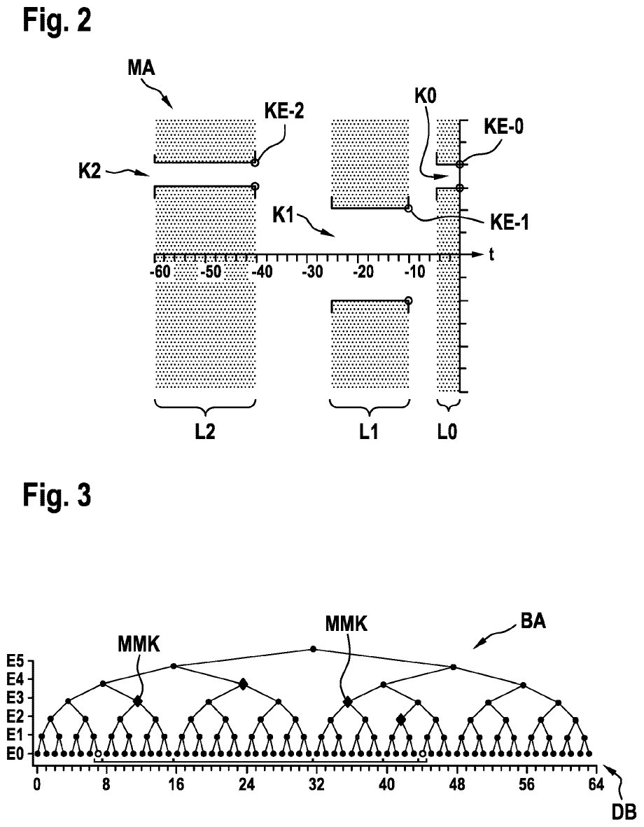

After the parallel tree generation, which took place in step PP1, depth-first searches are performed in step PP2, also through parallel processes. At this point, the shape of the applied mask MA plays a role. A possible mask MA is visualized in FIG. 2. This mask MA comprises three temporally separated corridors K0, K1, K2, which extend over different durations and each define a lower and upper limit for a signal. The lengths of the corridors K0, K1, K2 are designated L0, L1, L2.

If one wanted to check in the conventional way whether a trigger condition is fulfilled during the entire duration of a corridor, one would have to compare all signal values that fall within the corresponding time interval given by the corridor length individually with the corridor limits. This process would have to be repeated at every possible starting point of the corridor, i.e. for every possible mask position. The very high effort required for this is largely avoided according to the signal pattern recognition method according to the application by using the already generated trees BA in step PP2. In the arbitrary example of FIG. 3, a corridor of the mask MA extends from the seventh position to the forty-fourth position of the data block DB. During the depth-first search, the seventh position is considered first.

Starting from this position, the corresponding min-max pair in the next level, that of level E1, is considered. From this position in level E1, the search is made for associated values in the lower level, i.e. level E0, which in this case are the values in the sixth and seventh positions. The value at the sixth position lies outside the analyzed interval, so that the min-max pair in level E1, which is assigned to the values at the sixth and seventh positions, has no significance as regards to minima and maxima in the interval under consideration, that is, in the interval from the seventh to the forty-fourth position. Rather, in this case, the value at the seventh position itself already represents a min-max candidate of the interval under investigation.

The search for min-max candidates, which are denoted by MMK in FIG. 3, is then continued at the eighth position of the data block DB, i.e. at the second position of the interval under consideration. The eighth and ninth values of data block DB are assigned a common node in level E1 of the min-max tree BA. This node is initially considered as a new min-max candidate. In the same way, the sampling values at the tenth and eleventh positions of the data block DB are assigned a common min-max candidate in level E1. At this point in the tree run, i.e. depth-first search, there already exist two min-max candidates arranged next to each other in level E1. A large number of such individual steps of depth-first search are processed in parallel by means of the arithmetic units 5.

As long as a node is considered a min-max candidate MMK in a certain level E1, E2, . . . of the tree BA and the node directly adjacent to it in the same level E1, E2, . . . also represents a min-max candidate, it is checked whether the corresponding node in the next level E2, E3, . . . is also to be classified as a min-max candidate MMK. In the example shown in FIG. 3, a common min-max candidate MMK lying at level E3 is found for the values at the eighth to fifteenth positions. Going from this min-max candidate MMK one level further up, i.e. to level E4, one no longer finds a min-max candidate at this point, since the corresponding sampling values are distributed over the range from the zeroth to the fifteenth position and thus partly lie outside the interval under investigation. The found min-max candidate MMK located at level E3 is thus retained as the final min-max candidate.

The search for min-max candidates is then continued at the sixteenth position of the data block DB. In the manner described, another min-max candidate MMK is found, which covers the range from the sixteenth to the thirty-first position and is located in level E4. Further min-max candidates MMK cover the range from the thirty-second to the thirty-ninth or from the fortieth to the forty-third position. Finally, at the end of the interval under investigation, comparable to the beginning of the interval, a sampling value can be found which also counts as a min-max candidate, since all associated nodes in higher layers are also assigned sampling values that lie outside the interval under consideration.

Thus, in the case considered in FIG. 3, apart from the two sampling values located at the interval limits, four min-max candidates MMK were found. The number of min-max candidate MMK is thus significantly lower than the number of sampling values in the interval under investigation. This effect is increased with longer intervals. This also applies to cases where interval limits extend across data block limits.

The depth-first searches are performed for all mask lengths L0, L1, L2 and for all N possible positions of the mask MA. Here N is the length of the data block DB. As a result of the depth-first searches, also still in step PP2, a table with N rows, the number of columns of which corresponds to the number of different corridor lengths in L0, L1, L2, is filled out with minimum and maximum values. Each sampling time and each corridor length L0, L1, L2 is assigned a pair of a minimum value and a maximum value, which was obtained by comparing the min-max candidates MMK of the interval under consideration. In the case of FIG. 3, the minimum and maximum values must therefore be selected from two individual values located in level E0 and four pairs of values located in levels E2 to E4. The minimum and maximum values found are assigned to corridor endpoints KE-0, KE-1 and KE-2, based on the representation in FIG. 2. The verification of trigger conditions is thus possible by carrying out tests that only refer to individual points in time at which the corridor end points KE-0, KE-1, KE-2 are located as test points. The search of the entire windows of the mask MA, which have the lengths L0, L1, L2, is thus replaced by simple comparisons that can be carried out much faster.

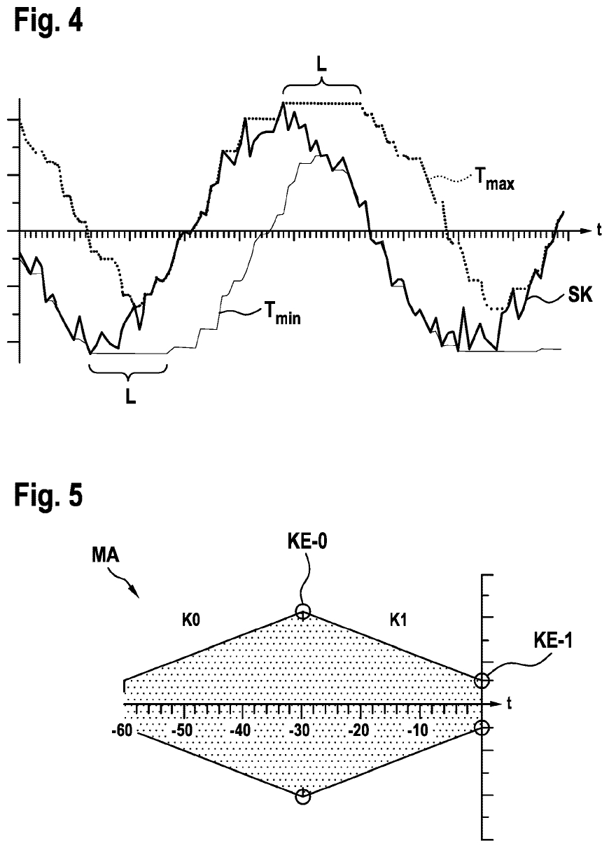

From the minimum and maximum values entered in the table TA, an envelope curve Tₘᵢₙ, Tₘₐₓ results, also still within the scope of step PP2, which depends on the signal curve SK and the applied mask MA, especially the corridor length L, and is shown as an example in FIG. 4. The signal curve SK has a modified sinusoidal shape according to FIG. 4. It is clearly visible that minima and maxima are each held for the corresponding duration due to the given corridor length L, which is expressed in horizontal portions of the envelope curve Tₘᵢₙ, Tₘₐₓ.

If it is to be checked at a specific point in time whether the signal fulfills the trigger condition not only at this point in time but also in the entire previous time interval, which extends over the duration L of the applied corridor K0, K1, K2, a comparison of Tₘᵢₙ and Tₘₐₓ with the corridor limits is sufficient. In this way, compliance with the trigger condition is checked for each of the sampling values, which are indexed with j, for example, which is done in step PP3. As a result of this check, a trigger function list TFL is filled in for each data block DB. Boolean values are entered into the trigger function list TFL, which indicate whether the trigger condition is fulfilled at the respective sampling position j. These values are called trigger value signals. The step PP3 is also carried out in the form of parallel data processing. A decisive advantage here is the fact that the check for compliance with the trigger condition can be carried out using the envelope curve Tₘᵢₙ, Tₘₐₓ for a large number of sampling times simultaneously. The evaluation at point j+1 does not have to wait for the result of the evaluation at point j.

After the trigger function list TFL has been completely filled in, step PP4 determines at which points the Boolean trigger value signal changes. If such a change is detected, entries j0, j1, j2 are made in a trigger list TLI. The entries j0, j1, j2, . . . are used as trigger times for the oscillographic representation.

FIGS. 5 to 7 refer to a mask MA which is modified compared to FIG. 2. In contrast to FIG. 2, in this case the mask MA is designed as a negative window. This means that all values that are either above an upper limit or below a lower limit are considered to be in the MA mask.

In the case of FIG. 5, the mask MA consists of two corridors K0, K1. The corridor K0 has a rising upper limit and a falling lower limit. Conversely, in corridor K1 there is a falling upper limit and a rising lower limit, so that the mask MA describes an overall diamond shape. The envelope curves Tₘᵢₙ, Tₘₐₓ, which are assigned to the corridors K0, K1, are generated in principle the same way as in the case of FIGS. 2 to 4. However, in the case of FIG. 5, it must be taken into account that the corridor limits do not represent constant values. The corridor limits varying over the course of the corridors K0, K1 are included in the structure of the curves Tₘᵢₙ, Tₘₐₓ in such a way that the gradients of the limits of the corridors K0, K1 are also expressed in gradients of the envelope curves Tₘᵢₙ, Tₘₐₓ. At the corridor endpoints KE-0, KE-1, the sampling values are used unchanged for building the envelope curve Tₘᵢₙ, Tₘₐₓ.

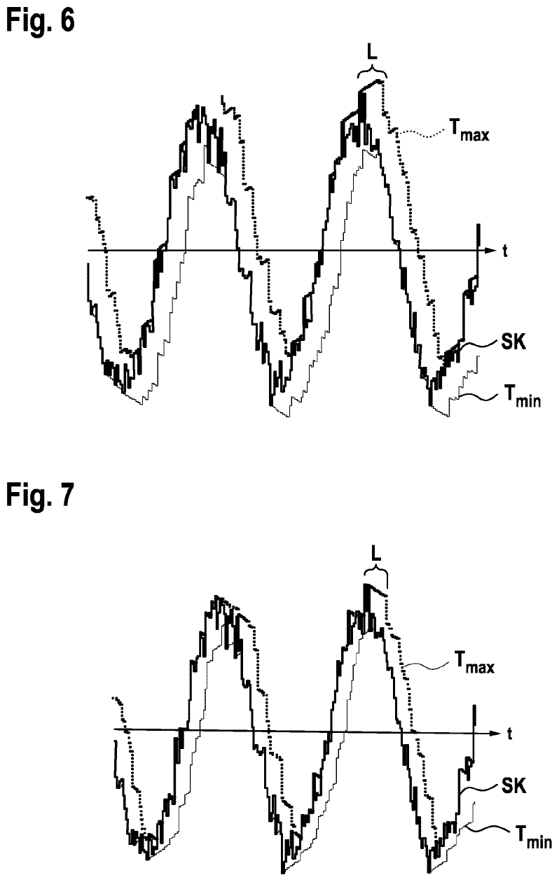

The further a point in time is from the corridor end points KE-0, KE-1, the more the measured value sampled at the corresponding point in time is increased or decreased according to the gradient of the limits of the corridors K0, K1 in order to reproduce the shape of the corridors K0, K1. Overall, this means that the signal curve SK is distorted to adapt to the shape of the corridors K0, K1 in order to form the envelope curves Tₘᵢₙ, Tₘₐₓ. This is expressed in FIGS. 6 and 7 in rising and falling portions of the envelope curves Tₘᵢₙ, Tₘₐₓ following minima and maxima of the signal curve SK. As soon as the modified envelope curves Tₘᵢₙ, Tₘₐₓ are generated, the data processing continues according to the procedure already explained in FIG. 1.

### LIST OF REFERENCE NUMERALS

1 signal processing device
2 data acquisition device
3 trigger device
4 ring memory
5 arithmetic unit
6 display device
BA min-max tree
DB data block
DS data stream
E0, E1, E2, . . . levels
K0, K1, K2, . . . corridors
KE-0, KE-1, . . . corridor endpoints, test points
L0, L1, L2, . . . corridor lengths
LV read operation
MA mask
MMK min-max candidate
PP1 . . . PP4 parallel processes
PS, PE start or end point
SK signal curve
SV write operation
TA table
TFL trigger function list
TLI trigger list
Tₘᵢₙ, Tₘₐₓ envelope curve

1. A method for signal pattern recognition, comprising the steps of:
discrete-time sampling of a continuous data stream for capturing sampling values that form a signal curve,
dividing the data stream into blocks, where the number of sampling values per block corresponds to a power of two,
building at least one min-max tree on each block, in which the sampling values are defined as the first layer of the tree and on the first layer further layers of the tree are built, which, in contrast to the first layer, are formed from min-max pairs, wherein each min-max pair is formed from a minimum and a maximum of the two pairs or sampling values lying in a last created or already existing layer, and wherein the building of the tree is performed by parallel data processing at least in a part of the layers which includes the first layer,
performing tree runs that partially cross block limits for each sampling time, for at least one corridor length specified by a signal mask, wherein within the entire corridor length each individual sampling value is initially defined as a min-max candidate and two consecutive min-max candidates are replaced by a min-max pair lying as the associated node in the layer above, provided that all sampling values assigned to the min-max pair lying as the associated node in the layer above also lie within a corridor having said corridor length, and identifying the minimum value and maximum value assigned to the respective sampling time and the corridor length on the basis of the min-max candidates found by the tree run, wherein one and a same min-max tree is used for a plurality of tree runs, to be performed in parallel,
generating an envelope curve belonging to the signal curve from the minimum and maximum values specific to the corridor length and each assigned to a sampling time,
testing a trigger condition given by the signal mask for each sampling time by comparison with the envelope curve, wherein at least part of the testing method is performed by parallel data processing and wherein Boolean trigger value signals are generated from sampling value to sampling value.

2. The method according to claim 1, wherein the corridor length to which the tree runs are made is less than the block length of each data block.

3. The method according to claim 1, wherein at least one envelope curve is generated for a corridor with constant upper and lower limits over the entire corridor length.

4. The method according to claim 1, wherein at least one envelope curve is generated for a corridor with varying upper and/or lower limit(s) over the corridor length, wherein the envelope curve is distorted according to deviation of the upper or lower limit from a limit given at a test point of the corridor in comparison to an envelope curve for a corridor with constant upper and lower limits.

5. The method according to claim 4, wherein the envelope curve is generated for a corridor with a constant gradient of the upper and/or lower limit(s), in portions.

6. The method according to claim 4, wherein the envelope curve is generated for a corridor which exclusively has portions in which gradients of the upper limit of a corresponding portion and of the lower limit of the same corresponding portion have different signs.

7. The method according to claim 1, wherein the block on which the min-max tree is to be constructed comprises at least 2¹⁰ sampling values and at most 2³⁰ sampling values.

8. The method according to claim 1, wherein the construction of the min-max tree, starting from the sampling values, is performed by parallel data processing at least up to half of the layers of the tree.

9. The method according to claim 1, wherein the number of tree runs performed in parallel corresponds at least to a square root of the number of sampling values per block.

10. The method according to claim 1, wherein the sampling values are acquired at time intervals of not more than 10 ns.

11. The method according to claim 1, wherein construction of the min-max trees and the tree runs are made in calculation steps which are longer than the time interval between two consecutive sampling values, wherein a total number of serial calculation steps per position of the signal mask is less than one due to parallelism of the data processing.

12. The method according to claim 1, comprising setting a trigger time, when the Boolean trigger value signal changes from “true” to “false” and entering the trigger times in a list.

13. The method according to claim 12, wherein entries in the list are made taking into account a trigger hold-off period.

14. The method according to claim 12, wherein entries in the list are made exclusively after release by a trigger counter.

15. A device for signal pattern recognition, with a data acquisition device and a trigger device coupled to the data acquisition device and configured to perform the method according to claim 1.

16. The device according to claim 15, wherein the trigger device comprises at least 128 arithmetic units configured for parallel data processing in the course of the building of the min-max trees and the tree runs.

17. The device according to claim 16, wherein the arithmetic units are configured for graphic display of sampling values.

18. The device according to claim 15, wherein the trigger device comprises a ring memory for storing at least three blocks of the data stream, whereby the trigger device is configured for uninterrupted processing of unfiltered sampling values.
